(19) United States
(12) Patent Application Publication
(10) Pub. No.: US 2012/0292623 A1
(43) Pub. Date: Nov. 22, 2012

(54) Thin-Film Semiconductor Device And Display Equipped With Same

(76) Inventors: Takao Shiraga, Morbara-shi (JP); Yuji Obara, Mobara-shi (JP); Masato Kasa, Mobara-shi (JP)

(21) Appl. No.: 13/471,632

(22) Filed: May 15, 2012

(30) Foreign Application Priority Data
May 21, 2011 (JP) 2011-114231
Apr. 2, 2012 (JP) 2012-083575

(51) Int. Cl. H01L 29/786

(52) U.S. Cl. 257/59; 257/57; 257/E29.273

(57) ABSTRACT

The invention provides a thin-film semiconductor device, which is equipped with a gate electrode, a source electrode, a drain electrode, an oxide semiconductor film, and an oxygen release insulator film. The oxygen release insulator film is in contact with at least a part of the oxide semiconductor film.

### BACKGROUND OF THE INVENTION

1. Field of the Invention

The present application claims priority of Japanese Patent Application No. 2011-114231 filed on May 21, 2011 and Japanese Patent Application No. 2012-083575 filed on Apr. 4, 2012, the disclosure of which is expressly incorporated by reference herein in its entirety.

The invention relates to one of field effect transistors, a thin-film semiconductor device having an oxide semiconductor film, and a display apparatus equipped with the thin-film semiconductor device.

2. Description of the Related Art

There has been proposed a thin-film semiconductor device having In—Ga—Zn—O based oxide semiconductor film which can be hereinafter called as IGZO-based oxide semiconductor film. For more detail, see JP 2011-40731 A.

FIG. 11 (PRIOR ART) shows a cross sectional view of a conventional thin-film semiconductor device. The thin-film semiconductor device is shown to include a substrate 10, a gate electrode 12G formed of aluminum, molybdenum or the like, a gate insulator film 11 formed of silicon oxides, silicon nitrides or the like, a IGZO-based oxide semiconductor 13, a source electrode and drain electrode 12S, 12D formed of aluminum, molybdenum or the like, and a protective film (i.e., a passivation film) 14 formed of silicon oxides, silicon nitrides or the like.

During the step of forming the protective film in an oxygen-free atmosphere by CVD or sputtering method, the conventional thin-film semiconductor device has drawbacks that due to energy applied for film formation oxygen isolates from the oxide semiconductor film and diffuses into the protective film. As a result, oxygen defection phenomenon leads to disappearance of TFT properties in the thin-film semiconductor device. For example, when forming the protective film by CVD method, due to heating energy in oxygen-free atmosphere, oxygen has a tendency to diffuse from the oxide semiconductor film into the protective film, thereby causing excess oxygen defection in the oxide semiconductor film. Moreover, when forming the protective film by sputtering, due to chemical energy in oxygen-free atmosphere oxygen has a tendency to diffuse from the oxide semiconductor film into the protective film, thereby causing excess oxygen defection in the oxide semiconductor film. The oxide semiconductor film is in contact with the protective film (e.g. SiOx protective film) lacking in oxygen. Accordingly, it is expected that due to chemical energy created by sputtering oxygen of the oxide semiconductor film diffuses across the protective film, and thereby causing the excess oxygen defection in the oxide semiconductor film.

For the reason as set forth above, the conventional thin-film semiconductor device generally represents TFT properties by heating it under oxygen atmospheric conditions (i.e., calcination), and diffusing oxygen into the oxide semiconductor film after the formation of the protective film. However, a process for producing a display apparatus such as a fluorescent display apparatus, equipped with the thin-film semiconductor device therein includes the steps of heating in oxygen-free atmosphere, including, for example, in carbon dioxide atmosphere, in an inert gas, and in vacuum, as well as, in an atmosphere lacking in oxygen which never cause the oxide semiconductor to represent TFT properties. The afore-mentioned heating steps may be the steps of adhering (coupling) and/or sealing by evacuation. Accordingly, oxygen hardly diffuses or dissipates across the oxide semiconductor film. A fluorescent display apparatus equipped with thin-film semiconductor device therein is generally calcined under atmospheric conditions together with other components or members of the fluorescent display apparatus at the same time, is then assembled (i.e., adhered to each other), and is then sealed by evacuation in vacuum. In this regard, the step of adhering (assembling) is carried out in carbon dioxide atmosphere, and the step of sealing by evacuation is carried out in vacuum. Accordingly, oxygen hardly diffuses or dissipates into the oxide semiconductor film during the steps of adhering and/or sealing by evacuation.

Furthermore, even if the thin-film semiconductor device thus obtained is independently heated, the thin-film semiconductor device which is formed of material that is not suited for heating environment in the presence of oxygen cannot be subjected to heating in an oxygen atmosphere, and thus fails to diffuse oxygen into the oxide semiconductor film.

### SUMMARY OF THE INVENTION

In light of the afore-mentioned drawbacks and problems, the inventors proposes a novel thin-film semiconductor device capable of diffusing oxygen into an oxide semiconductor film even if the thin-film semiconductor device is heated under oxygen-free atmosphere, or is manufactured under oxygen-free atmosphere. The inventors also propose a novel display apparatus equipped with such a thin-film semiconductor device.

Specifically, the invention is to provide a thin-film semiconductor device, which includes a gate electrode, a source electrode, a drain electrode, an oxide semiconductor film, and an oxygen release insulator film. The oxygen release insulator film is in contact with at least a part of the oxide semiconductor film.

Preferably, the oxygen release insulator film may be configured to release oxygen due to energy applied for film formation and/or heating of the thin-film semiconductor device.

Preferably, the energy applied for film formation may be energy applied for protective film formation.

Preferably, the oxygen release insulator film may be formed of manganese composite oxide.

Preferably, the oxygen release insulator film may be formed of oxidized transition metal.

Preferably, the manganese composite oxide may be manganese aluminum composite oxide.

Preferably, the oxidized transition metal may be manganese dioxide.

Preferably, the gate electrode, the source electrode, and the drain electrode may be formed of metal oxide film.

In other aspect, the invention provides a display equipped with the thin-film semiconductor device as described previously.

Preferably, the display may be obtained by heating and adhering. Preferably, the display may be a fluorescent display.

### BRIEF DESCRIPTION OF THE DRAWINGS

The invention may be put into practice in various ways and a number of embodiments will be described by way of example to illustrate the invention with reference to the accompanying drawings, in which:

FIG. 1 shows cross-sectional views of one embodiment of a thin-film semiconductor device in accordance with the invention and a fluorescent display apparatus equipped with the thin-film semiconductor device therein;

FIG. 2 illustrates the detailed structure of the thin-film semiconductor of FIG. 1;

FIG. 3 shows parts of process for producing one embodiment of a fluorescent display apparatus in accordance with the invention (PC1-PC3);

FIG. 4 shows parts of process for producing one embodiment of a fluorescent display apparatus in accordance with the invention (PC4-PC6);

FIG. 5 shows parts of process for producing one embodiment of a fluorescent display apparatus in accordance with the invention (PC7-PC9);

FIG. 6 shows (a) oxygen release properties of manganese dioxide, and (b) source and drain current characteristics of thin-film semiconductor device having an oxygen release film formed of manganese dioxide;

FIG. 7 shows source and drain current characteristics of thin-film semiconductor device having an oxygen release film formed of manganese aluminum composite oxide;

FIG. 8 shows light resistance properties of thin-film semiconductor device having an oxygen release film formed of manganese aluminum composite oxide;

FIG. 9 shows a shift phenomenon of thin-film semiconductor device having an oxygen release film formed of manganese aluminum composite oxide;

FIG. 10 is an exemplary anode drive circuit of fluorescent display apparatus equipped with one embodiment of thin-film semiconductor device in accordance with the invention; and

FIG. 11 is a cross-sectional view of a conventional thin-film semiconductor.

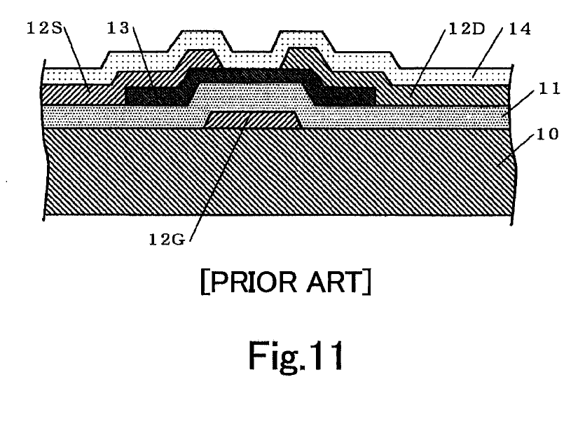

### DETAILED DESCRIPTION OF THE PREFERRED EMBODIMENTS

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

One embodiment of a thin-film semiconductor device in accordance with the invention can be formed such that an insulator film formed of material, which is capable of releasing oxygen when heating the thin-film semiconductor device, is in contact with an oxide semiconductor film. In this regard, the afore-mentioned term “insulator film” can be also hereinafter called as “an oxygen release insulator film”. Moreover, the oxygen release insulator film can release oxygen due to heating energy of CVD or chemical energy of sputtering or sputters during the step of film formation for the manufacture of the thin-film semiconductor device.

Material which is suited for the oxygen release insulator film includes, but is not limited to, transition metal oxide such as manganese dioxide (MnO2) or manganese aluminum composite oxide (MnAlOx).

The transition metal oxide (i.e., oxidized transition metal) is subjected to heating or thermal deposition so as to release oxygen. As a result, the above transition metal oxide undergoes a change into non-oxygen release transition metal oxide. For example, manganese dioxide (MnO2) is subjected to heating or thermal deposition so as to release oxygen, thereby turning into manganese trioxide (Mn2O3) which does not release oxygen even if it is subjected to heating.

One embodiment of a thin-film semiconductor device in accordance with the invention has an oxygen release insulator film, and thus can release oxygen when being subjected to energy for film formation (i.e., film formation energy). Accordingly, the oxygen thus released diffuses across the oxide semiconductor film, thereby representing TFT properties. Furthermore, a display apparatus, in particular, a fluorescent display apparatus, equipped with the embodiment of the thin-film semiconductor device is capable to diffuse oxygen from the oxygen release insulator film to the oxide semiconductor film during heating step in which the display apparatus is heated under oxygen-free atmosphere at a temperature of 300 Celsius degrees or above, preferably 400 Celsius degrees or above and below the crystallization temperature of the oxide semiconductor film, thereby representing TFT properties. Generally, the fluorescent display apparatus is calcined under atmospheric conditions, is adhered or assembled in carbon dioxide atmosphere, and is evacuated and sealed in a vacuum. As such, the thin-film semiconductor device can be heated together with other components or members of the fluorescent display device (for example, an anode electrode, a grid, and a cathode) during the afore-mentioned steps including calcination, adhering (i.e., assembling), and sealing by evacuation. Accordingly, even if there is oxygen deficiency in the oxide semiconductor film during the film formation step, the defect(s) can be eliminated or recovered during either of the subsequent calcination, adhering, or evacuation step.

The following examples are offered for illustrative purposes only, and are not intended to limit the scope of the present invention in any way. Indeed, various modifications of the invention in addition to those shown and described herein will become apparent to those skilled in the art from the foregoing description and the following examples and fall within the scope of the appended claims.

### EXAMPLES

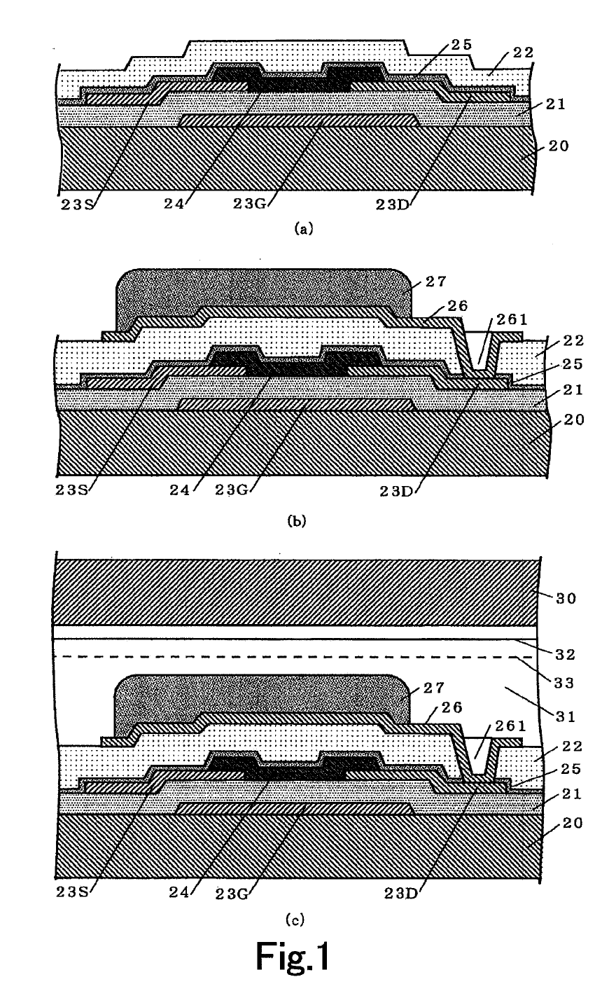

The invention will be further hereinafter described with reference to FIGS. 1-9 attached hereto.

Referring to FIG. 1, FIG. 1(a) shows a cross-sectional view of one embodiment of a thin-film semiconductor device in accordance with the invention; FIG. 1(b) shows a cross-sectional view of the thin-film semiconductor device of FIG. 1(a) over which an anode electrode of a fluorescent display apparatus is disposed; and FIG. 1(c) shows a cross-sectional view of a fluorescent display apparatus in which the thin-film semiconductor device of FIG. 1(b) is kept inside an airtight container.

With reference to FIG. 1(a), the thin-film semiconductor device has a glass substrate 20, a gate electrode 23G formed on the glass substrate 20, and a gate insulator film 21 surrounding the gate electrode 23G Optionally, a base (not shown) can be formed between the substrate 20 and the gate electrode 23G so as to prevent any impure element(s) from diffusing. There can be provided a source electrode 23S, a drain electrode 23D, and an oxide semiconductor film 24 on or over the gate insulator film 21. An oxygen release insulator film 25 can be disposed such that it surrounds or covers the source electrode 23S, the drain electrode 23D, and the oxide semiconductor film 24. A protective film 22 can be formed such that it surrounds or covers the oxygen release insulator film 25. The oxygen release insulator film 25 can be formed such that it is in contact with at least a part of the oxide semiconductor film 24.

Each of the source electrode 23S and the drain electrode 23D has one portion opposed to the oxide semiconductor film 24, and other portion which externally extends from the one portion opposed to the oxide semiconductor film 24 and is not opposed to the oxide semiconductor film 24. In other words, the portion opposed to the oxide semiconductor film 24 is in contact with the oxide semiconductor film 24. On the other hand, the other portion which is not opposed to the oxide semiconductor film 24 is configured to be connected to the metallic wiring or metallic terminal (not shown).

Next, material for the thin-film semiconductor device will be described in detail.

In one embodiment of the invention, the gate electrode 23G is formed of aluminum (Al). However, the gate electrode 23G may be formed of molybdenum, titanium, or the like. In one embodiment of the invention, the base, the gate insulator film 21, and the protective film 22 are formed of silicon oxide (SiOx). However, the base, the gate insulator film 21, and the protective film 22 may be formed of silicon nitride (SiNx), aluminum oxide (AlxOy), and etc. One embodiment of the invention, the source electrode 23S and the drain electrode 23D are formed of transparent conductive material of indium tin oxide (ITO). However, the source electrode 23S and the drain electrode 23D may be formed of other conductive material. In the shown embodiment of the invention (FIG. 1), if the gate electrode 23G is formed of metal, in particular reducible metal, oxygen is removed from the oxide semiconductor film 24 due to metal reduction even if the gate insulator film 21 is disposed between the oxide semiconductor film 24 and the gate electrode 23G In order to prevent oxygen diffusion from the oxide semiconductor film 24 into the gate electrode 23G, the source electrode 23S, or the drain electrode 23D, the gate electrode, 23G, the source electrode 23S, and the drain electrode 23D are preferably formed of metal oxide conductive material such as ITO. In a case where metal oxide is employed for the gate electrode material as substitute for metal, the film thickness of the oxygen release insulator film can be made thinner, or the reliability can be enhanced while maintaining the same film thickness.

In the one embodiment of the invention, the oxide semiconductor film 24 is formed of IGZO oxide semiconductor. However, other oxide semiconductor may be employed. In the one embodiment of the invention, the oxygen release insulator film 25 is formed of manganese oxide (MnOx (1≦x≦2). However, the oxygen release insulator film 25 can be formed of transition metal oxide such as oxides of silver (Ag), tungsten (W), iron (Fe), cobalt (Co), lead (Pb), titanium (Ti), nickel (Ni), niobium (Nb), SUSx, or the like. A lead (Pb)-containing flitted glass can be employed as lead (Pb).

The oxygen release insulator film 25 can be also formed of manganese-based composite oxide (MnXOx), such as manganese aluminum composite oxide (MnAlOx), in which X may be silicon (Si), titanium (Ti), or yttrium (Y) in addition to aluminum (Al).

In a case where the oxygen release insulator film 25 is formed of manganese aluminum composite oxide (MnAlOx), it would be superior to the oxygen release insulator film formed of manganese dioxide (MnO2) in terms of on/off rise time with respect to TFT properties of thin-film semiconductor device.

The manganese aluminum composite oxide (MnAlOx) is selected such that the ratio of Mn to Al (i.e., Mn:Al) is between 25:75 mol % and 60:40 mol %. Preferably, the ratio of Mn to Al (Mn:Al) is 33:67 mol %. In a case where the ratio of Mn:Al is 15:85 mol %, due to excess amount of aluminum TFT properties would be deteriorated. To the contrary, in the case of the ratio of Mn:Al being 80:20 mol %, due to excess amount of manganese the intrinsic effect of aluminum is significantly reduced.

With reference to FIG. 1(b), an anode electrode (i.e., a pixel electrode) 26 is formed on the protective film 22 of the thin-film semiconductor device of FIG. 1(a), and a phosphor layer or film 27 is formed on the anode electrode 26. The anode electrode 26 is opposed to the oxide semiconductor film 24 via the protective film 22 which is located on the opposite side of the gate insulator film 21 with respect to the oxide semiconductor film 24. The gate electrode 26 can be formed of metal oxide such as ITO. The anode electrode 26 externally extends beyond the opposing oxide semiconductor film 24. Accordingly, a part of the anode electrode 26 which is not opposed to the oxide semiconductor film 24 is connected via a terminal portion 261 to the drain electrode 23D.

In a case where the anode electrode 26 is formed of metal, oxygen is often removed from the oxide semiconductor film 24 due to metal reduction even if the protective film 22 is formed between the oxide semiconductor 24 and the anode electrode 26. For the reason as set forth above, it is undesirable that any of metallic electrode, metallic wiring, and metallic terminal is disposed within a distance of 30 μm from the oxide semiconductor film 24 even if an insulator film intervenes therebetween. In a case where the electrode is formed within a distance of 30 μm, it is preferable to employ a metallic oxide conductive material.

FIG. 1(c) shows a fluorescent display apparatus in which the thin-film semiconductor device as shown in FIG. 1(b) is disposed inside an airtight container.

The airtight container is shown to have a glass substrate 20, a glass front plate 30 opposed to the substrate 20, and a lateral member (i.e., a side member) disposed between the substrate 20 and the front plate 30.

In the airtight container, there are provided the thin-film semiconductor device as shown in FIG. 1(b), and a filament for electron source (i.e., a cathode) 32, and a control electrode (i.e., a grid) 33.

Next it will be hereinafter described with respect to the timing of heating the oxygen release insulator film 25 in the thin-film semiconductor device as shown in FIGS. 1(a) and 1(b), as well as, the fluorescent display apparatus as shown in FIG. 1(c).

As shown in FIG. 1(a), the thin-film semiconductor device may be heated after the protective film 22 is formed. Alternatively, as shown in FIG. 1(b) the thin-film semiconductor device may be heated after the anode electrode and etc. of the fluorescent display apparatus are formed. Alternatively, as shown in FIG. 1(c) the thin-film semiconductor device may be heated after the thin-film semiconductor device and other components or members of the fluorescent display apparatus are disposed inside the airtight container.

In order to reduce or simplify the steps needed for the process for manufacture of the fluorescent display apparatus, it may be desirable to heat the thin-film semiconductor device and other components of the fluorescent display apparatus at the same time after the fluorescent display apparatus is assembled as shown in FIG. 1(c).

In one embodiment of the invention as shown in FIGS. 1(b) and 1(c), the thin-film semiconductor device can be used as a pixel selective circuit for the fluorescent display apparatus. However, the inventive thin-film semiconductor device may be also used as a drive circuit for a grid, a cathode, and etc. Moreover, the thin-film semiconductor device may be used as a substrate for an organic EL display apparatus, a liquid crystal display apparatus (LCD), or a TFT-equipped display apparatus.

The electron source for the fluorescent display apparatus is not limited to the afore-mentioned filament, and may include a filed emission-type electron source.

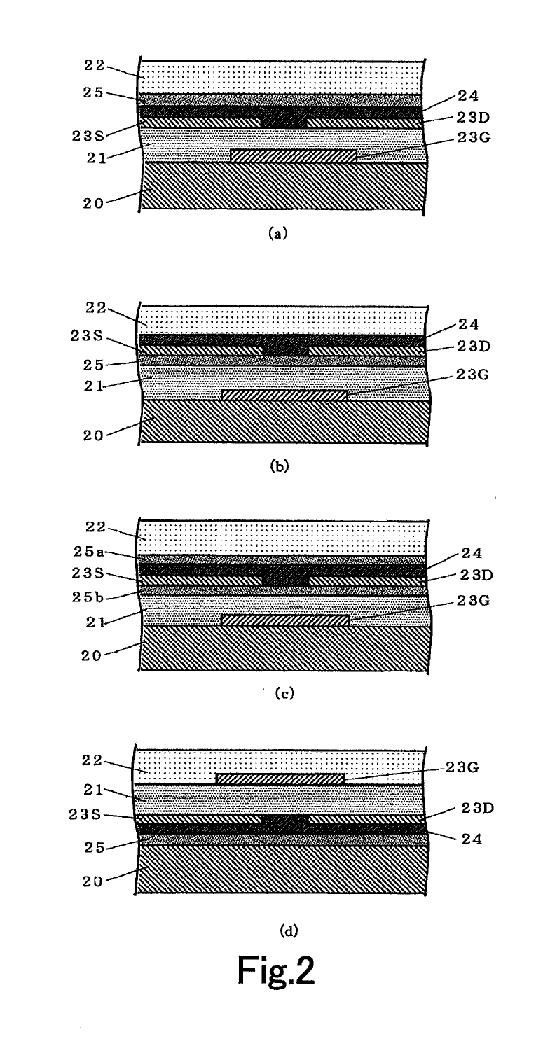

With reference to FIG. 2, it will be hereinafter described a location where the oxygen release insulator film is formed in the thin-film semiconductor of FIG. 1(a).

Referring to FIG. 2(a), the oxygen release insulator film 25 is formed between the oxide semiconductor film 24 and the protective film 22. The oxide release insulator film 25 is in contact with one whole surface of the oxide semiconductor film 24.

Referring to FIG. 2(b), the oxygen release insulator film 25 is formed between the gate insulator film 21 and the source electrode 23S, and between the gate insulator film 21 and the drain electrode 23D. As such, the oxygen release insulator film 25 is in contact with the oxide semiconductor film 24 between the source electrode 23S and the drain electrode 23D.

Referring to FIG. 2(c), the oxygen release insulator film 25, including reference numerals 25a and 25b, is formed both sides of the oxide semiconductor film 24, and is in contact with the oxide semiconductor film 24 in the same location as shown in FIGS. 2(a) and 2(b).

Referring to FIG. 2(d), the oxygen release insulator film 25 is formed in the gate electrode-topped thin-film semiconductor device. In this embodiment, the oxygen release insulator film 25 is formed between the substrate 20 and the oxide semiconductor film 24.

In the case of the thin-film semiconductor device as shown in FIGS. 2(a) to 2(d), transition metal oxide can be used for the gate insulator film 21 and the protective film 22 such that the gate insulator film 21 and the protective film 22 can also serve as an oxygen release insulator film.

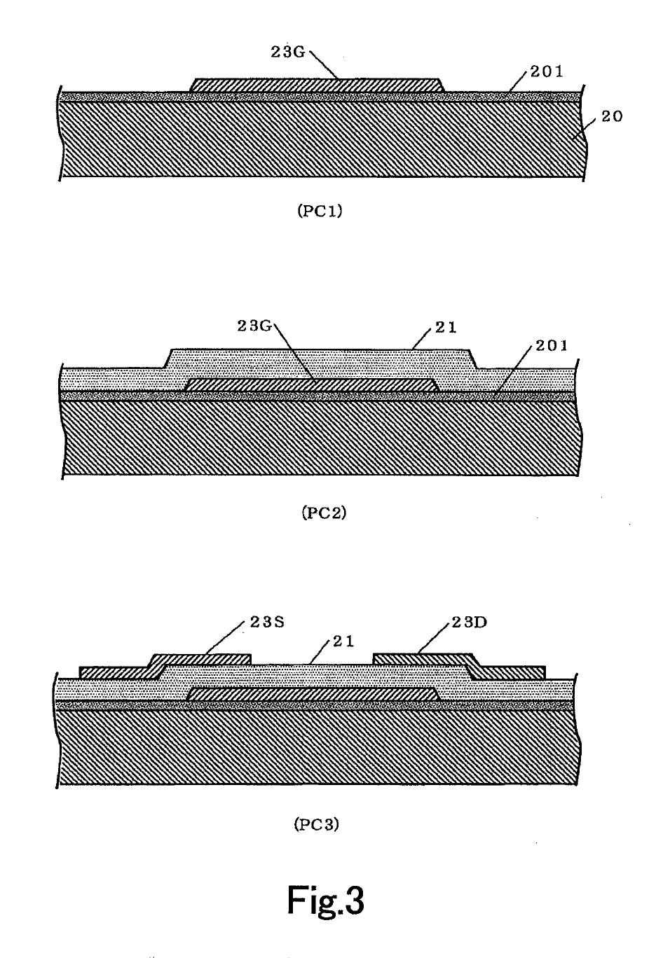

Next a process for producing the fluorescent display apparatus as shown in FIG. 1(c) will be hereinafter described in detail with reference to FIGS. 3-5.

During the step PC1 of FIG. 3, the base 201 of silicon oxide (SiOx) is formed on the glass substrate 20 by CVD method, the gate electrode 23G of aluminum is formed on the base 201 by sputtering. During the step PC2 of FIG. 3, the gate insulator film 21 of silicon oxide (SiOx) is formed on the gate electrode 23G by CVD method such that the gate electrode 23G is surrounded or covered by the gate insulator film 21. During the step PC3 of FIG. 3, ITO source electrode 23S and the drain electrode 23D are formed on the gate insulator film 21 by sputtering.

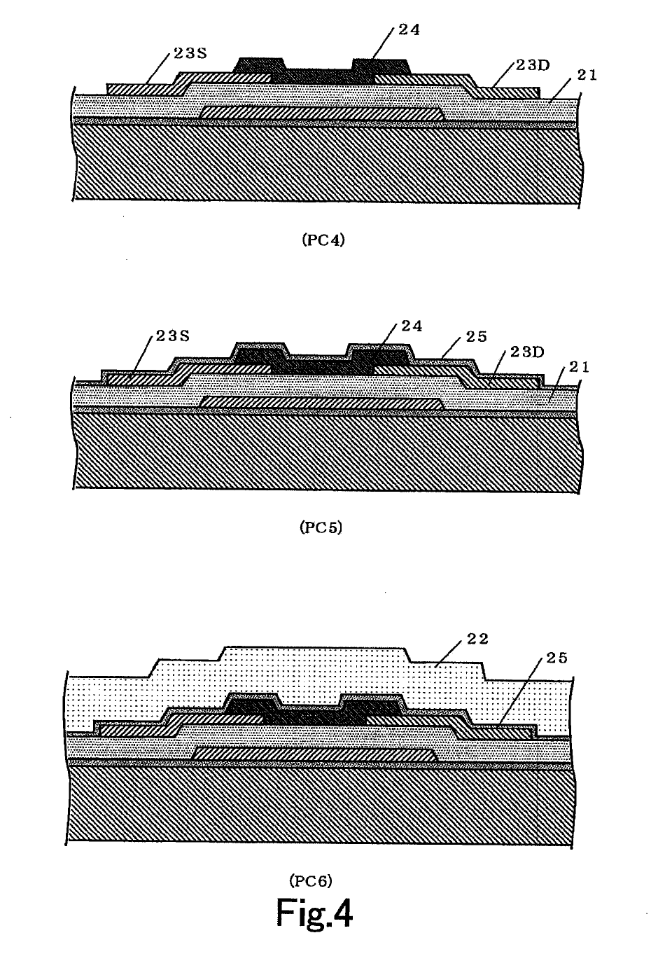

During the step PC4 of FIG. 4, IGZO-based oxide semiconductor film 24 is formed by sputtering such that the source electrode 23S, the drain electrode 23D, and the gate insulator film 21 are surrounded or covered by the IGZO-based oxide semiconductor film 24. During the step PC5 of FIG. 4, the oxygen release insulator film 25 of manganese dioxide (MnO2) is formed by use of reactive sputters such that the oxide semiconductor film 24, the source electrode 23Q the drain electrode 23D, and the gate insulator film 21 are surrounded or covered by the oxygen release insulator film 25. During the step PC6 of FIG. 4, the protective film 22 of silicon oxide (SiOx) is formed such that the oxygen release insulator film 25 is surrounded or covered by the protective film 22.

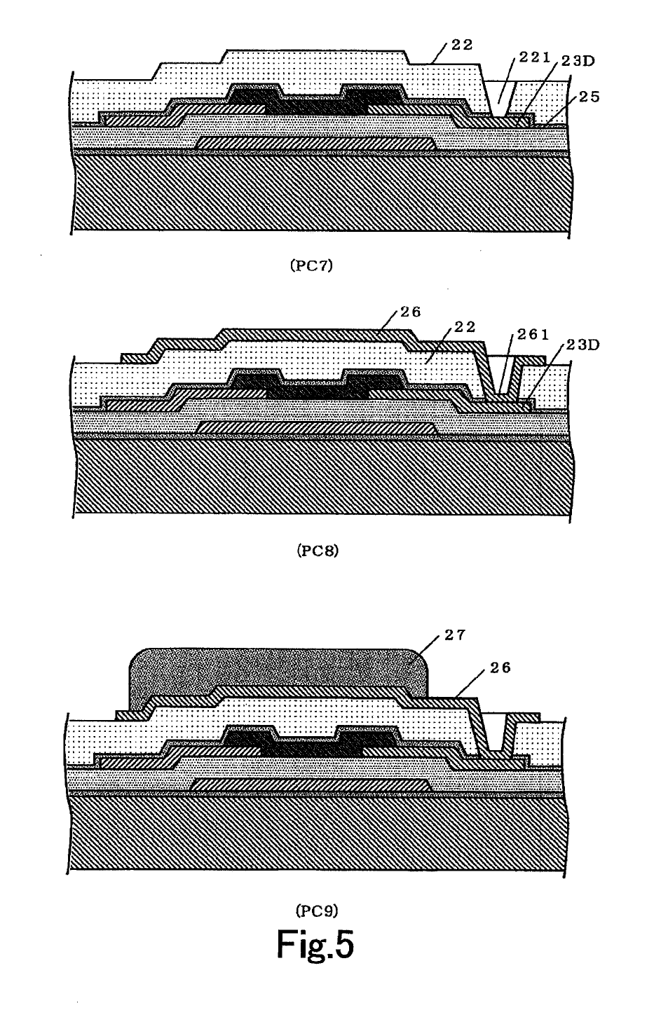

During the step PC7 of FIG. 5, a through-hole 221 can be formed by etching. During the step PC8 of FIG. 5, there is provided ITO anode electrode 26 and the terminal portion 261 connected to the drain electrode 23D on and/or in the protective film 22. During the step PC9 of FIG. 5, a phosphor layer or film 27 is formed on the anode electrode 26 by printing.

The thin-film semiconductor device as obtained in the step PC9 is calcined together with the filament for electron source 32 as shown in FIG. 1(c), the control electrode 33 as shown in FIG. 1(c), and etc. under atmospheric conditions at the same time, and the substrate 20, the front plate 30, and the lateral member 31 as shown in FIG. 1(c) are coupled or adhered to each other in carbon dioxide atmosphere, thereby forming the container which is comprised of the substrate 20, the front plate 30, and the lateral member 31. In this situation, the fitted glass is softened so as to serve as an adhesive. The container thus obtained can be sealed by evacuation in a vacuum. As a result, a vacuum, airtight container can be formed.

In the afore-mentioned process, the oxygen release insulator film 25 of the thin-film semiconductor device is capable of releasing oxygen due to energy applied for thin film or layer formation (i.e., CVD or sputtering step). The thin-film semiconductor device is heated in order of calcination under atmospheric conditions, in turn, adhering, and, in turn, sealing by evacuation. Due to the heating the oxygen release insulator film 25 is capable of releasing oxygen. At the same time, manganese dioxide (MnO2) turns into manganese trioxide (Mn2O3). The conversion of manganese dioxide into manganese trioxide can occur throughout overall steps as mentioned previously. In particular, while manganese dioxide is low resistance material (i.e., a material of semiconductor level), manganese trioxide is high resistance material, thus providing enough resistance between the gate and the drain.

Moreover, the calcination under atmospheric conditions can be carried out at a temperature of about 480 Celsius degrees, and the adhering can be carried out at a temperature between about 480 Celsius degrees and about 500 Celsius degrees. The crystallization temperature of IGZO-based oxide semiconductor film is about 600 Celsius degrees.

The afore-mentioned process is directed to one embodiment in which the oxygen release insulator film 25 is formed by manganese dioxide (MnO2). The oxygen release insulator film of manganese aluminum composite oxide (MnAlOx) can be formed in a similar manner.

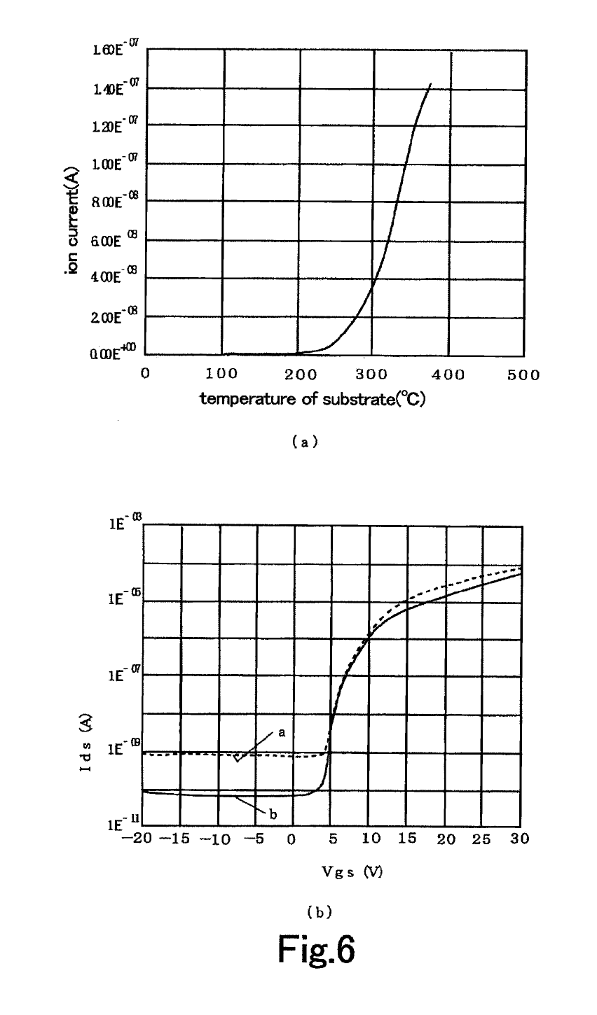

With referring to FIG. 6(a), oxygen release properties during the heating of manganese dioxide (MnO2) is described based on thermal desorption spectroscopy (i.e., TDS). In FIG. 6(a), a horizontal axis represents a temperature (Celsius degrees) of the substrate over which manganese dioxide (MnO2) film is formed, and a vertical axis represents ion current (A) which corresponds to the oxygen release (amount).

The ion current begins to flow at a temperature (i.e., a substrate temperature) of about 200 Celsius degrees, and dramatically increase at a temperature of from 250 Celsius degrees to 400 Celsius degrees. In view of the above, it is understood that manganese dioxide can release oxygen during the steps of calcination, adhering, and sealing by evacuation.

Next, source/gate voltage and drain/source current properties after calcination of the thin-film semiconductor device having manganese dioxide-based oxygen release insulator film as shown in FIG. 1(a) will be hereinafter described in detail with reference to FIG. 6(b). In FIG. 6(b), a horizontal axis represents gate/source voltage (Vgs) (V), and a vertical axis represents drain/source current (Ids) (A). FIG. 6(a) shows the properties of the thin-film semiconductor device as shown in FIG. 1(a) which is subjected to calcination under at atmospheric conditions, and FIG. 6 (b) shows the properties of the thin-film semiconductor device as shown in FIG. 1 (a) which is subjected to calcination under atmospheric conditions, and then adhering.

The thin-film semiconductor device which is calcined under atmospheric conditions represents TFT properties, as shown in FIG. 6(a). Moreover, the thin-film semiconductor device which is subjected to calcination, and then, adhering reduces off current (FIG. 6(b)) in comparison with the thin-film semiconductor device which is only subjected to calcination (FIG. 6(a)), and thus allowing for enhanced TFT properties. It appears that this is because manganese dioxide (MnO2) turns into manganese trioxide (Mn2O3), thus allowing for stabilization and enhanced level of resistance.

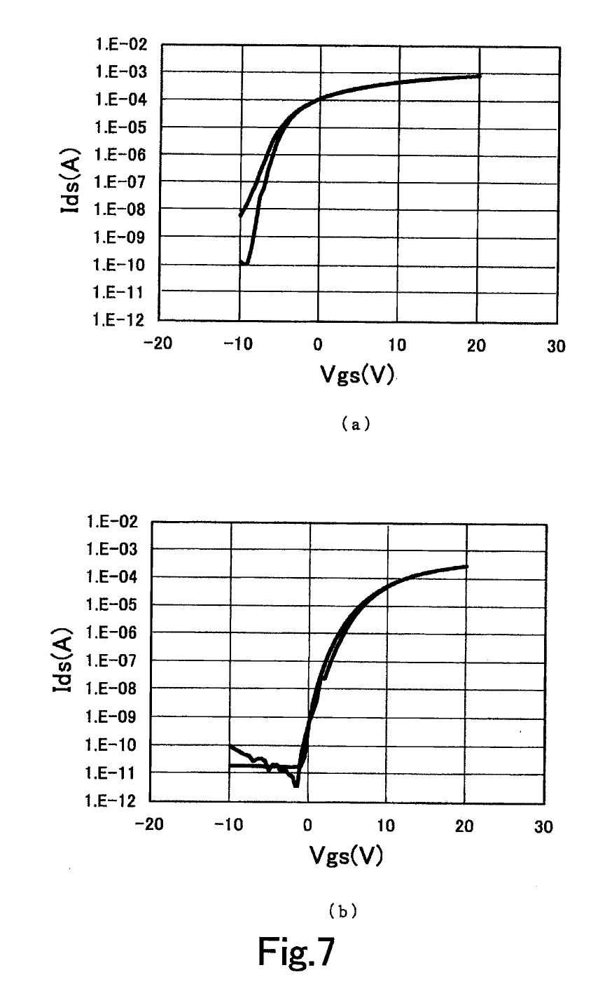

Next, with reference to FIGS. 7-9 it will be hereinafter described TFT properties of the thin-film semiconductor device having manganese aluminum composite oxygen release insulator film (FIG. 1).

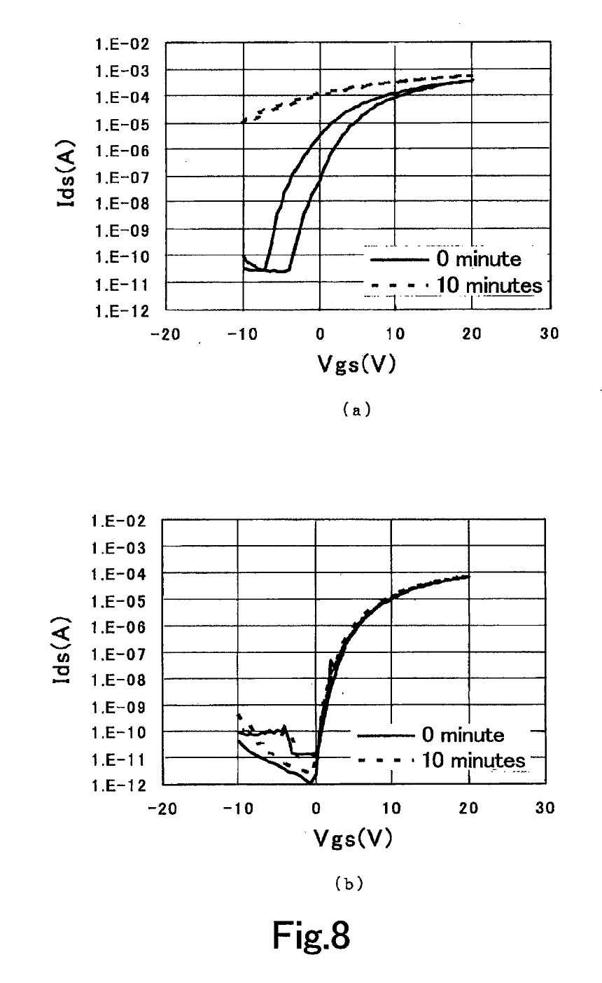

First, FIGS. 7 and 8 illustrate gate/source voltage and drain/source current properties of the thin-film semiconductor device which is calcined. In FIGS. 7 and 8, a horizontal axis represents gate/source voltage (Vgs) (V), and a vertical axis represents drain/source current (Ids) (A). There graphs illustrate the properties when the gate/source voltage is changed within a range between −10V and 20V.

In FIG. 7, FIG. 7(a) shows properties of the thin-film semiconductor device having no oxygen release insulator film, and FIG. 7(b) shows properties of the thin-film semiconductor device having an oxygen release insulator film.

Referring to FIG. 7(a), a large amount of drain/source current (Ids) flows even if gate/source voltage is 0 (V). Referring to FIG. 7(b), as the gate/source voltage is 0 (V), only small amount of drain/source current flows, which means enough rise characteristics. Accordingly, the thin-film semiconductor device having the oxygen release insulator film switches from on state to off state at the gate/source voltage (V) of 0, and thereby allowing for providing enough switch characteristics, as shown in FIG. 7(b).

FIG. 8 shows light resistance properties of the thin-film semiconductor device. For more detail, FIG. 8 illustrates the relationship between the period of time to irradiate the thin-film semiconductor device with light and drain/source current. FIG. 8(a) shows properties of the thin-film semiconductor device having no oxygen release insulator film, and FIG. 8(b) shows properties of the thin-film semiconductor device having oxygen release insulator film.

Referring to FIG. 8(a), the drain/source current becomes larger at gate/source voltage of 0 when irradiating the thin-film semiconductor device with light for a period of 10 minutes. Referring to FIG. 8(b), the drain/source current does not change even if the thin-film semiconductor device is subjected to light irradiation for a period of 10 minutes. Accordingly, the thin-film semiconductor device having the oxygen release insulator film has enough or enhanced light resistance properties, as shown in FIG. 8(b).

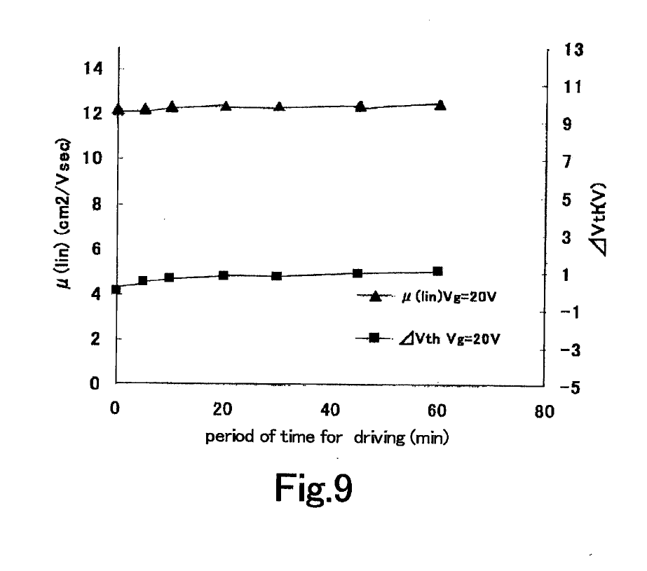

FIG. 9 shows a shift phenomenon of thin-film semiconductor device having an oxygen release film formed of manganese aluminum composite oxide. For more detail, FIG. 9 shows the relationship between time (min) for driving the thin-film semiconductor device having an oxygen release insulator film at gate voltage (Vg) of 20 (V), and the degree of electron movement μ ((lin)(cm2/Vsec)) and rise characteristics ΔVth (V).

FIG. 9 demonstrates that the degree of electron movement (μ) and rise characteristics (ΔVth) are constantly maintained even if the thin-film semiconductor device is driven for a long period of time. For more detail, see FIG. 9.

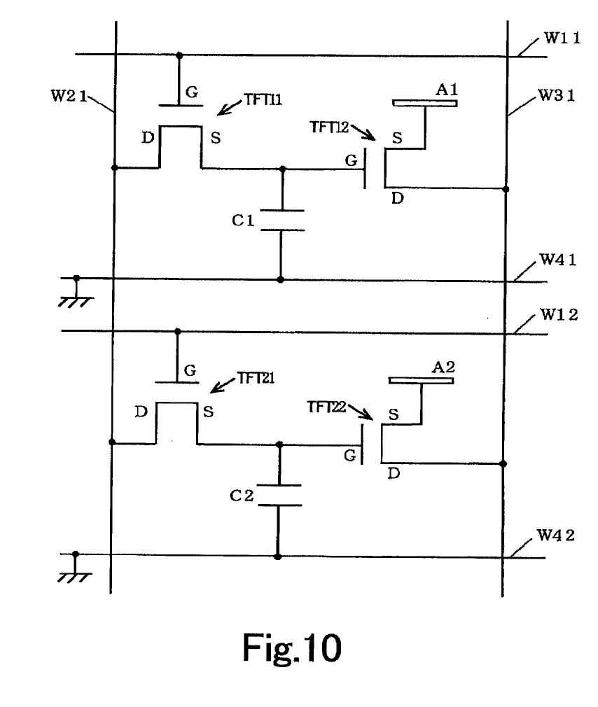

FIG. 10 is an exemplary anode drive circuit of a fluorescent display apparatus equipped with one embodiment of the thin-film semiconductor device in accordance with the invention. In FIG. 10 in which a plurality of dotted anodes is disposed in the form of matrix, only two anode electrodes A1 and A2 are shown.

A drive circuit for the anode electrode A1 and A2 is comprised of switching elements TFT11 and TFT21, driving elements TFT12 and TFT22, and storage capacitors C1 and C2. The elements TFT 11 through TFT 22 employ one embodiment of the thin-film semiconductor device in accordance with the invention.

The elements TFT11 through TFT22 have a gate electrode G, a source electrode S, and a drain electrode D. The gate electrodes G of the elements TFT11 and TFT21 are connected to scanning lines W11 and W12 respectively; the drain electrodes D of the elements TFT11 and TFT21 are connected to data line (i.e., a line for providing data signal) W21; the drain electrodes D of the element TFT12 and TFT 22 are connected to input voltage (filament power voltage) (Vh) (=Eb (anode electrode)) (common) line W31 (i.e., a line for supplying input voltage); and one end portions of the storage capacitors C1 and C2 are connected to GND (anode, grid off potential) lines W41 and W42 respectively.

While FIG. 10 shows an anode drive circuit of fluorescent display apparatus, the thin-film semiconductor device in accordance with the invention may be used as a drive circuit for a pixel electrode of other types of display apparatus such as an organic EL display apparatus and a liquid crystal display apparatus.

While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A thin-film semiconductor device, comprising:
a gate electrode;
a source electrode;
a drain electrode;
an oxide semiconductor film; and
an oxygen release insulator film, the oxygen release insulator film being in contact with at least a part of the oxide semiconductor film.

2. The thin-film semiconductor device according to claim 1, wherein the oxygen release insulator film is configured to release oxygen due to energy applied during film formation, and/or, heating of the thin-film semiconductor device.

3. The thin-film semiconductor device according to claim 2, wherein the energy applied during film formation is energy applied during a protective film formation.

4. The thin-film semiconductor device according to claim 1, wherein the oxygen release insulator film is formed of manganese composite oxide.

5. The thin-film semiconductor device according to claim 1, wherein the oxygen release insulator film is formed of oxidized transition metal.

6. The thin-film semiconductor device according to claim 4, wherein the manganese composite oxide is manganese aluminum composite oxide.

7. The thin-film semiconductor device according to claim 5, wherein the oxidized transition metal is manganese dioxide.

8. The thin-film semiconductor device according to claim 1, wherein the gate electrode, the source electrode, and the drain electrode are formed of metal oxide.

9. A display apparatus equipped with the thin-film semiconductor device according to claim 1.

10. The display apparatus according to claim 9 obtained by heating and adhering.

11. The display apparatus according to claim 10, wherein the display apparatus is a fluorescent display apparatus.
